(19) United States
(12) Patent Application Publication
(10) Pub. No.: US 2015/0237732 A1
(43) Pub. Date: Aug. 20, 2015

(54) LOW-PROFILE PACKAGE WITH PASSIVE DEVICE

(71) Applicant: QUALCOMM Incorporated, San Diego, CA (US)

(72) Inventors: Mario Francisco Velez, San Diego, CA (US); Daeik Daniel Kim, San Diego, CA (US); Young Kyu Song, San Diego, CA (US); Xiaonan Zhang, San Diego, CA (US); Jonghae Kim, San Diego, CA (US); Changhan Hobie Yun, San Diego, CA (US); Chengjie Zuo, Santee, CA (US)

(73) Assignee: QUALCOMM Incorporated, San Diego, CA (US)

(21) Appl. No.: 14/200,684

(22) Filed: Mar. 7, 2014

Related U.S. Application Data
(60) Provisional application No. 61/941,308, filed on Feb. 18, 2014.

(51) Int. Cl. H05K 1/18; H01L 21/48; H05K 3/40; H05K 1/03; H05K 1/16; H01L 23/498; H05K 1/11

(52) U.S. Cl. CPC H05K 1/182; H01L 23/49827; H01L 23/49811; H01L 21/486; H01L 21/4853; H01L 23/49894; H05K 1/115; H05K 1/0306; H05K 1/165; H05K 3/4038; H05K 2201/10015; H05K 2201/10242; H05K 2201/10984

(57) ABSTRACT

A low-profile passive-on-package is provided that includes a plurality of recesses that receive corresponding interconnects. Because of the receipt of the interconnects in the recesses, the passive-on-package has a height that is less than a sum of a thickness for the substrate and an interconnect height or diameter.

### CROSS-REFERENCE TO RELATED APPLICATIONS

This application claims the benefit of U.S. Provisional Application No. 61/941,308, filed on Feb. 18, 2014, the contents of which are incorporated by reference in their entirety.

### TECHNICAL FIELD

This application relates to integrated circuit package substrates, and more particularly to a low-profile package with a passive device.

### BACKGROUND

In a passive-on-glass (PoG) package, passive components such as inductors and capacitors are integrated onto a glass substrate. The PoG package may then be coupled to a circuit board along with semiconductor packages to form a complete working device such as a radio frequency (RF) front end. As compared to a conventional coupling of discrete passive devices to a circuit board, the use of a PoG package is much more compact. In addition, a PoG package is less expensive than integrating the passive devices into the dies containing the active devices for an electronic system because glass substrates are relatively inexpensive in comparison to crystalline semiconductor substrates.

Although a PoG package is thus an attractive alternative for providing passive components for an electronic system, PoG design faces a number of challenges. In particular, there is an ever-increasing need to reduce the dimensions of the electronics incorporated into mobile devices. As users demand more compact devices, the electronics contained within the devices must shrink in size accordingly. One of the dimensions that must shrink for a PoG package is its height with regard to the underlying circuit board. A straightforward way to reduce the PoG package height is to reduce the thickness of its glass substrate. But glass is inherently brittle. A glass substrate is thus prone to cracking if its thickness is reduced excessively such as less than 150 or 100 microns. The problem does not go away if the passive components are instead integrated onto a semiconductor substrate because such substrates also are brittle and become too fragile if excessively thinned. Since the issues are largely the same regardless of the type of substrate used to support passive components, the term “passive-on-package” is used herein to denote a package containing passive components integrated onto a glass, semiconductor, or organic substrate.

Another issue with reducing the glass substrate thickness is the inductance for embedded inductors formed by through-substrate vias within the glass substrate. The coil or loop for each embedded inductor is formed by a pair (or more) of the through-substrate vias. For example, a first through-substrate via in an embedded inductor may extend from a first surface of a substrate to a lead or conductor formed on an opposing second surface for the substrate. The conductor also couples to a second through-substrate via in the embedded inductor that extends from the second surface back to the first surface. Current driven into the first through-substrate via from the first surface will thus flow through the conductor on the second surface and loop back down to the first surface in the second through-substrate via. This current loop provides the inductance for the resulting embedded inductor. The inductance depends upon (among other factors) the area encompassed by the current loop. If the through-substrate via lengths are decreased by thinning the substrate, the resulting inductance for the embedded inductor will also shrink. As the thickness for the substrate is reduced, the height or length of through-substrate vias through such a reduced-thickness substrate is of course reduced accordingly. For example, a substrate that is 200 microns thick may have through-substrate vias that extend through such a thickness and thus also have a corresponding length of 200 microns. But if the substrate is just 100 microns thick, the through-substrate vias would then have a length of just 100 microns. Reducing the package height for a PoG package will thus tend to reduce the inductances for its inductors. The necessary inductance is thus also a barrier to reducing PoG package heights.

The solder balls or other types of interconnects that couple a passive-on-package to the underlying circuit board are another factor that limit passive-on-package height reduction. To better illustrate these challenges in passive-on-package design, a conventional passive-on-package 100 is shown in FIG. 1. Package 100 has a thickness or height H₁ with regard to an underlying circuit board (not illustrated) that depends upon a thickness T for a substrate 104 as well as a diameter d₁ for each of a plurality of solder balls 112. Substrate 104 includes a plurality of through-substrate vias 102 that couple from a board-facing surface 108 of substrate 104 to an opposing surface 106. Vias 102 may form 3-dimensional passive structures such as an embedded inductor 103. As discussed above, an inductance for embedded inductor 103 reduces as the thickness T for substrate 104 is reduced. Solder balls 112 couple to corresponding pads 110 on surface 108. Since solder balls 112 project from pads 110 on surface 108, one can immediately appreciate that if the diameter d₁ of solder balls 112 is reduced, the height H₁ for package 100 will be reduced accordingly. However, solder balls 112 are prone to cracking if diameter d₁ is reduced excessively. In particular, lead-free solder is required in modern systems due to the environmental concerns raised by the use of conventional lead-containing solder. But lead-free solder is typically more brittle than conventional solder so that its use demands a certain minimum diameter for solder balls 112. Both the thickness T of substrate 104 and the diameter d₁ for solder balls 112 thus cannot be reduced excessively without sacrificing strength and board level reliability (BLR) as well as the required inductance for inductor 103. The height H₁ thus must satisfy these minimum values for conventional passive-on-packages. This minimum height requirement reduces the resulting density of systems incorporating package 100.

Accordingly, there is a need in the art for more compact package designs with passive devices.

### SUMMARY

To provide a low-profile package substrate including a passive device, a first side of a substrate includes a plurality of recesses. As used herein, a low-profile package substrate including a passive device may also be denoted as passive-on-package. Each recess receives a corresponding interconnect such as a solder ball or metal pillar. A redistribution layer on the first side of the substrate electrically couples to at least a subset of the interconnects. The substrate includes a plurality of through-substrate vias. In one embodiment, a pair of the through-substrate vias forms an embedded inductor. The redistribution layer may include a lead or conductor that extends from a first one of the recesses to one of the through-substrate vias forming the inductor. In this fashion, the interconnect received in the first recess electrically couples through the conductor in the redistribution layer to the first through-substrate via in the embedded inductor. The substrate may include additional embedded inductors having through-substrate vias coupled to corresponding interconnects through the redistribution layer in this fashion.

### BRIEF DESCRIPTION OF THE DRAWINGS

FIG. 1 is a cross-sectional view of a conventional passive-on-package.

FIG. 2 is a cross-sectional view of a low-profile passive-on-package in accordance with an embodiment of the disclosure.

FIG. 3A is a cross-sectional view of a low-profile passive-on-package in accordance with an embodiment of the disclosure.

FIG. 3B is a plan view of a recessed side of the low-profile passive-on-package of FIG. 3A.

FIG. 4A is a cross-sectional view of a substrate after formation of through-substrate vias.

FIG. 4B is a cross-sectional view of the substrate of FIG. 4A after deposition of a redistribution layer on a die-facing surface of the substrate and a passivation layer on the redistribution layer.

FIG. 4C is a cross-sectional view of the substrate of FIG. 4B after formation of recesses on a board-facing surface of the substrate.

FIG. 4D is a cross-sectional view of the substrate of FIG. 4C after deposition of a redistribution layer on the board-facing surface of the substrate and a passivation layer over the redistribution layer.

FIG. 4E is a cross-sectional view of the substrate of FIG. 4D after placement of solder balls in the recesses to complete manufacture of a low-profile passive-on-package.

FIG. 5 is a flowchart for a manufacturing method in accordance with an embodiment of the disclosure.

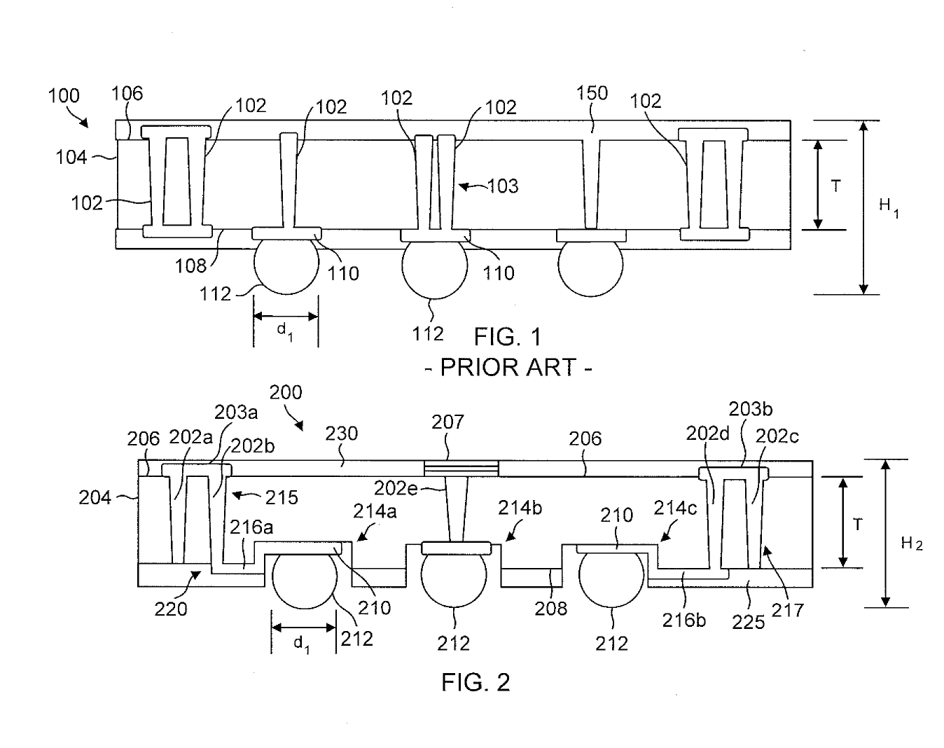

Embodiments of the present disclosure and their advantages are best understood by referring to the detailed description that follows. It should be appreciated that like reference numerals are used to identify like elements illustrated in one or more of the figures.

### DETAILED DESCRIPTION

A low-profile passive-on-package is provided that includes a first side having plurality of recesses. Each recess may receive a corresponding interconnect such as a solder ball, a metal post, or a metal cylinder. The following discussion will be directed to a solder ball interconnect embodiment but it will be appreciated that other suitable types of interconnects may be used in alternative embodiments. The substrate also includes a plurality of through substrate vias that extend from the first surface to an opposing second surface of the substrate. A redistribution layer on the first side of the substrate electrically couples to one or more of solder balls in the recesses. For example, the redistribution layer may comprise a patterned metal layer that forms leads or conductors coupled to corresponding ones of the solder balls received in the recesses. A redistribution layer conductor couples between a corresponding solder ball to an end of a corresponding through-substrate via. Since the redistribution layer is adjacent the first surface of the substrate, the end of a through-substrate via that the redistribution layer conductor couples to is also adjacent the first surface.

A pair (or more) of the through substrate vias may be coupled together through a conductor on the second surface of the substrate to form an embedded inductor. For example, the redistribution layer may include a first conductor extending from an interconnect in a first one of the recesses to a through-substrate via in the embedded inductor. Similarly, the redistribution layer may include a second conductor extending from an interconnect in a second one of the recesses to another through-substrate via in the embedded inductor. The interconnect in the first recess thus electrically couples through the embedded inductor to the interconnect in the second recess. In this fashion, a current driven from the interconnect such as a solder ball in the first recess conducts through the embedded inductor to, for example, a solder ball in the second recess. This is quite advantageous because the embedded inductor may have a relatively robust inductance as each of its through-substrate vias is relatively long in that they extend from the first side for the substrate to the opposing second side. Yet the resulting passive-on-package has an advantageously low profile because the solder balls are received in the recesses. The portion of each solder ball that is received in the corresponding recess makes no contribution to the package height.

In addition, the substrate may include through-substrate vias that extend from a corresponding ones of the recesses to the opposing second surface of the substrate. To distinguish between the various through-substrate vias, a through-substrate via extending from the first side of the substrate to the opposing second side is denoted herein as a first through-substrate via. In contrast, a through-substrate via extending from a recess to the opposing second side of the substrate is also denoted herein as second through-substrate via. A second through-substrate via is shorter than a first through-substrate via by the depth of the corresponding recess. This reduced length is advantageous when driving an integrated capacitor on the second surface of the substrate such as a metal-insulator-metal (MIM) capacitor because the reduced length of the second through-substrate via coupling to the capacitor has less parasitic resistance and inductance as compared to a coupling from a first through substrate via. This is quite advantageous because a substrate may be relatively thick so as to be robust against breakage and warpage and so as to support relatively-long first through-substrate vias that provide increased inductance to embedded inductors yet the same substrate supports second through-substrate vias that may drive integrated capacitors with reduced parasitic resistance and inductance.

Given the receipt of the interconnects such as solder balls in the substrate recesses, the substrate need not be excessively thinned and the solder balls may still have a sufficiently robust diameter to resist cracking yet the resulting passive-on-package has a reduced thickness or height because the solder balls are received in the blind vias or recesses. Since the substrate need not be excessively thinned, the substrate may have a thickness that is sufficiently large so as to be robust to breakage and warpage. In addition, note that embedded inductors formed using a pair of through-substrate vias extending through the substrate benefit from the relatively robust substrate thickness despite the resulting passive-on-package having a reduced height due to the solder-ball-receiving recesses. As discussed earlier, an inductor's inductance is a function of the loop area enclosed by the winding or coil forming the inductor. With regard to the embedded inductors disclosed herein, the inductor coil may be formed by a pair (or more) of first through-substrate vias. The substrate may then have a thickness of a sufficient magnitude to achieve a robust inductance from the inductor yet the package height is reduced because the solder balls are received in the corresponding recesses.

In addition, the thickness for the substrate may be sufficiently robust so as to reduce substrate fragility, warpage, and breakage yet the package height is reduced because the solder balls are received in the corresponding recesses. Similarly, the solder balls may each have a sufficiently robust diameter so as to reduce cracking and increase board level reliability. Although the solder balls may have such a robust diameter, these diameters only partially contribute to the package height due to the solder balls being received within the recesses. These and other advantages may be better appreciated through the following discussion of example embodiments.

### Example Embodiments

FIG. 2 illustrates an example passive-on-package 200 that includes a substrate 204 having the minimum thickness T discussed with regard to conventional passive-on-package 100. For example, if substrate 204 comprises glass, thickness T may be, for example, at least 100 microns so that substrate 204 is sufficiently robust to provide the desired board level reliability (BLR). In general, the minimum thickness T depends upon the properties of the substrate 204. For example, more robust types of glass may be thinned to more than 100 microns. Conversely, the glass may be less robust such that the thickness T must be 150 microns or greater. Similar limitations on the thickness T would occur if substrate 204 is a semiconductor substrate such as silicon. Alternatively, substrate 204 may comprise an organic substrate. A plurality of interconnects such as solder balls 212 for interconnecting to a circuit board or another package substrate may also have the same minimum thickness d₁ discussed with regard to conventional passive-on-package 100. The minimum thickness d₁ for a solder ball 212 depends upon its composition. For example, if solder balls 212 comprise lead-free solder, they are more brittle and would thus require a greater minimum thickness d₁ as compared to lead-containing embodiments. Despite these minimum dimensions being satisfied, passive-on-package 200 has a height H₂ that is reduced in comparison to the height H₁ of passive-on-package 100 because substrate 204 receives solder balls 212 in corresponding blind vias or recesses 214 formed in a first side 208 of substrate 204. The height H₂ of passive-on-package 200 is thus reduced by approximately the depth of blind vias or recesses 214.

Passive-on-package 200 may include one or more first through-substrate vias such as first through-substrates 202a, 202b, 202c, and 202d extending from first surface 208 of substrate 204 to an opposing second surface 206 of substrate 208. First through-substrate via 202a couples through a lead or conductor 203a on second surface 206 of substrate 204 to first through-substrate via 202a to form an embedded inductor 215. Similarly, first through-substrate via 202d couples through a conductor 203b to first through-substrate via 202c to form an embedded inductor 217. Each embedded inductor 215 and 217 has an advantageously robust inductance since a thickness T for substrate 204 is not excessively thinned. For example, the current loop area encompassed by inductor 215 is a function of the length (among other factors) of each first through-substrate via 202a and 202b. In turn, the first through-substrate via lengths are a function of the thickness T for substrate 204. Since the thickness T need not be excessively reduced to achieve an advantageously low package height H₂ for passive-on-package 200, first through-substrate vias such as vias 202a and 202b may be relatively long to provide enhanced inductance for inductor 215.

The coupling to inductors 215 and 217 may occur through a redistribution layer 220. For example, a solder ball 212 received in a recess 214a couples to first through-substrate via 202b in inductor 215 through a redistribution layer conductor 216a and recess pad 210 formed from redistribution layer 220. Another solder ball may couple through an analogous redistribution layer conductor and pad (not illustrated) to first through-substrate via 202a to complete the coupling to inductor 215. An analogous coupling may be provided with regard to embedded inductor 217. For example, a solder ball 212 received in a recess 214c couples to first through-substrate via 216b in inductor 217 through a redistribution layer conductor 216b and a recess pad 210. In one embodiment, redistribution layer 220 may be deemed to comprise a means for electrically coupling certain ones of the recess-received interconnects to corresponding ones of the first through-substrate vias.

In contrast to the first through-substrate vias, second through-substrate vias have a reduced length. For example, a second through-substrate via 202e extends from a recess 214b to second surface 206 of substrate 204. As compared to a length for the first through-substrate vias that substantially equals the thickness T for substrate 204, second through-substrate via 202e has a length that is shortened by the depth or height of recess 214b. This reduced length reduces the parasitic inductance and resistance in a coupling of second through-substrate via 202e to a capacitor 207 integrated onto surface 206 of substrate 204. In one embodiment, capacitor 207 may comprise a metal-insulator-metal (MIM) capacitor.

Recesses 214 may also include an adhesive (not illustrated) to aid in retaining solder balls 212. The first and second through-substrate vias 202 may serve both an electrical coupling function as well as a heat transfer role. Second through-substrate vias are particularly useful for heat transfer from second surface 206 to solder balls received in the corresponding recesses due to their reduced length as compared to first through-substrate vias. A passivation layer or solder resist layer 230 may cover second surface 206. Similarly, a passivation layer or solder resist layer 225 may cover first surface 208 of substrate 204. Passivation layers 230 and 225 may comprise a wide variety of suitable materials such as silicon nitride, dielectric polymers such as polymide, or organic polymers.

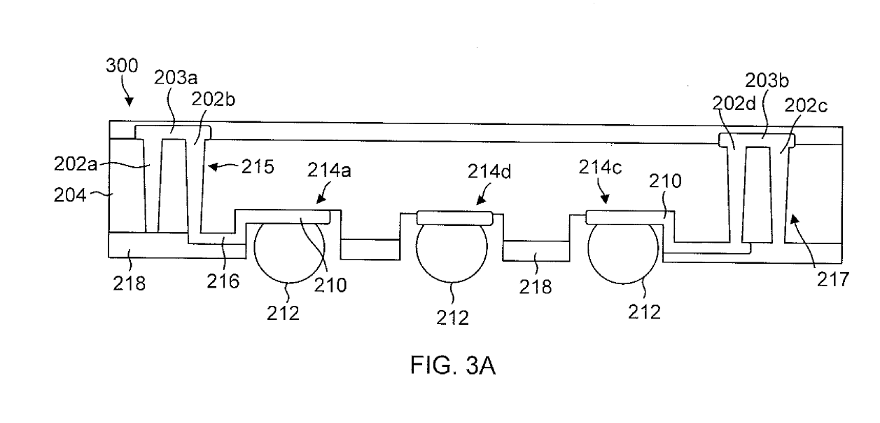

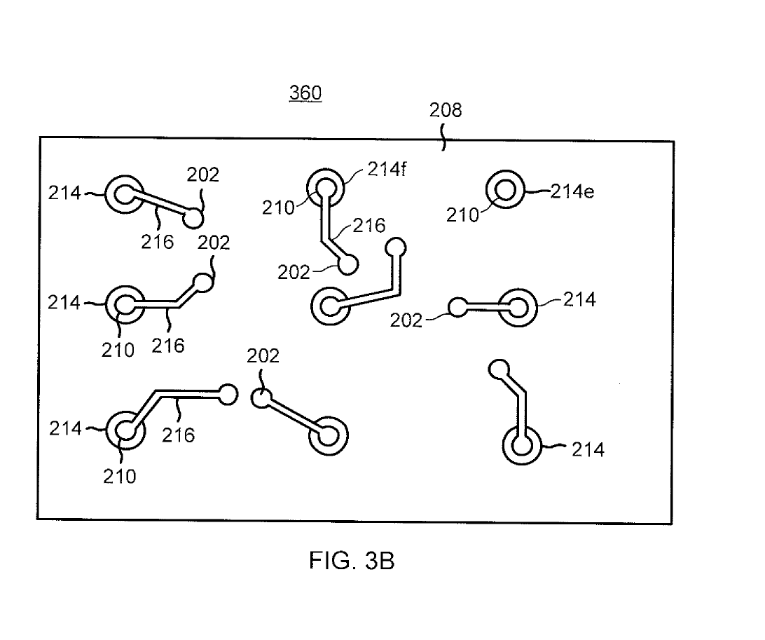

A passive-on-package 300 shown in FIG. 3A comprises one of many alternative embodiments. In this embodiment, surface 206 includes a recess 214d that receives a solder ball 212 that does not couple to any through-substrate vias or other structures, Solder ball 212 in recess 214d thus functions only to mechanically couple passive-on-package 300 to a corresponding circuit board or additional substrate (not illustrated) as opposed to having an electrical function. The remaining elements in passive-on-package substrate 300 are as discussed with regard to passive-on-package 200.

A plan view of surface 208 of a substrate 360 for an exemplary passive-on-package is shown in FIG. 3B to better illustrate a layout for redistribution layer pads 210 and redistribution layer conductors 216 to first through-substrate vias 202. An example recess 214f includes a redistribution layer pad 210 that couples through a redistribution layer conductor 216 to a first through substrate via 202. In contrast, a recess 214e includes a redistribution layer pad 210 that does not couple to any redistribution layer conductor. Pad 210 in recess 214e may instead couple to a second through-substrate via (not illustrated). Alternatively, recess 214e may merely have a mechanical bonding purpose as discussed with regard to recess 214d of FIG. 3A.

The enhanced thickness T for the disclosed substrates such as substrate 204 shown in FIG. 2 enables the elimination of temporary carriers that would otherwise be required during manufacture if the substrate thickness were reduced. In addition, the length for first through-substrate vias 202 may be increased, which leads to increased inductance and better quality factors for inductors such as embedded inductors 215 and 217. In addition, better heat flow through substrate 204 may be achieved using second through-substrate vias such as second through-substrate via 202e that are shortened as compared to the substrate thickness T. This same shortening of via 202e also reduces its resistance, which increases the quality factor for capacitors driven through them such as for capacitor 207. The resulting reduced signal path length through such second through-substrate vias is also beneficial in enhancing signal integrity. In addition, because the portion of solder balls 212 received in recesses 214 does not contribute to the package height, solder balls 212 may maintain a minimum diameter, which also improves board level reliability (BLR) and resistance to solder ball cracking. Blind vias or recesses 214 also accommodate the use of adhesive, which further improves BLR. Finally, blind vias or recesses 214 act as a stencil during a ball drop stage in manufacture so that solder balls 212 may be received in the corresponding recesses 214 with less error. An example manufacturing process will now be discussed.

### Example Manufacturing Process

The following discussion will be directed to wafer-level-process (WLP) embodiments in which the substrate used to support passive components in a passive-on-package is processed as part of a wafer (or panel) before being diced into individual packages. But it will be appreciated that the processes discussed herein may also be applied individually to substrates that have been diced from the wafer as compared to processing the wafer (or panel) as a unit. Regardless of whether a WLP process is used to manufacture passive-on-packages to achieve a reduced height, the reduced-height passive-on-packages disclosed herein receive interconnects such as solder balls within corresponding blind vias or recesses.

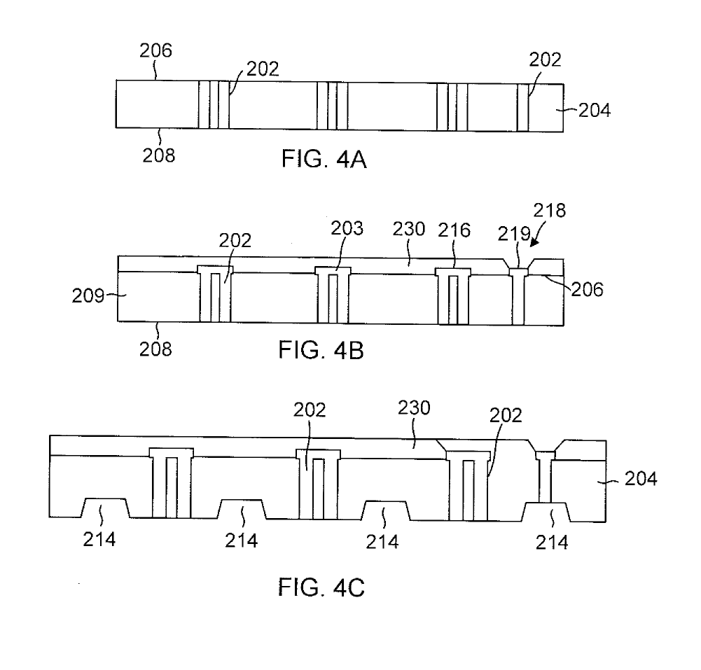

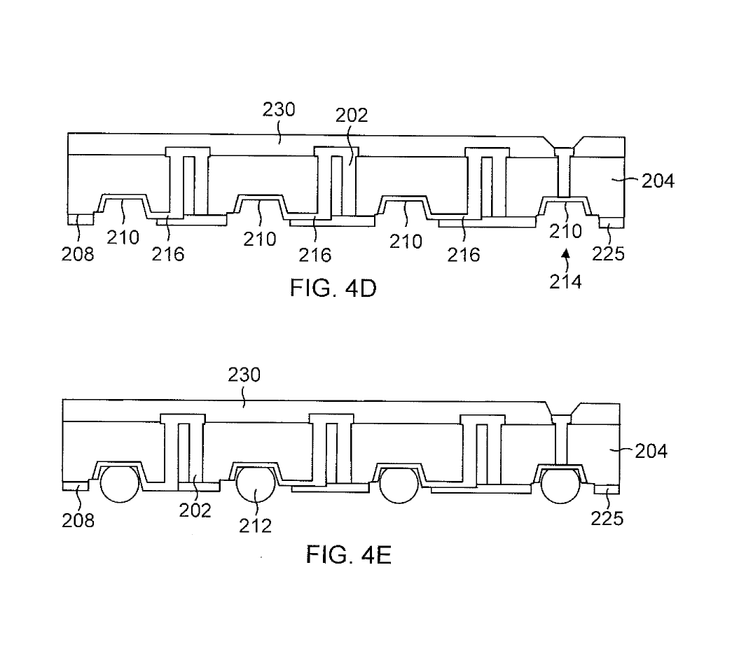

An example manufacturing process flow is shown in FIGS. 4A through 4E. As illustrated in FIG. 4A, a substrate 204 such as a glass panel or wafer (or semiconductor wafer) is processed to form through substrate vias 202. Alternatively, substrate 204 may comprise a laminated organic panel. To form through-substrate vias, substrate 204 may be laser drilled, mechanically drilled, or etched to form vias that are then electroplated with copper, nickel, or other suitable metals to form through-substrate vias 202. Alternatively, an electroless process may be used instead of electroplating. After deposition of metal to form through-substrate vias 202, first surface 208 and opposing second surface 206 for substrate 204 may then be polished. Since recesses are not formed yet on first surface 208 (which may be the board-facing surface), the length distinction between first and second through-substrate vias has not yet been created.

As shown in FIG. 4B, second surface 206 of substrate 204 may be processed with a patterned metal layer such as a copper or nickel metal layer through, for example, photolithographic techniques to form conductors 203 connecting corresponding through-substrate vias to form inductors. In addition, the deposition of a MIM structure on surface 206 to form any desired capacitors (not illustrated) may also be performed at this time. Moreover, passivation layer 230 may be deposited over surface 208 at this manufacturing stage. Should contact be required to certain subsequent through-substrate vias such as for heat transfer or signal conduction to a die, the patterned metal layer forming conductors 203 may also be patterned to form pads such a pad 219. In such an embodiment, passivation layer 230 may include pad openings such as a pad opening 218 to expose pad 219.

Surface 208 may then be etched or drilled to form blind vias or recesses 214 as shown in FIG. 4C. With regard to etching of recesses 214, either wet or dry etching techniques may be used. Alternatively, reactive ion etching may be used to etch recesses 214. With regard to drilling, laser or mechanical drilling techniques are suitable. In the cross-sectional view of FIG. 4C, recesses 214 do not intersect with any through-substrate vias 202 such that all these illustrated vias are first-surface vias. Alternatively, a recess may intersect with a through-substrate via such as discussed earlier with regard to recess 214e of FIG. 2 to form a second through-substrate via 202e (shown only in FIG. 2).

As illustrated in FIG. 4D, backside redistribution layer pads 210 and conductors 216 may then be deposited onto surface 208 of substrate 204. For example, a mask layer (not illustrated) may be patterned to include openings for the plating of copper, nickel, or other suitable metals to form pads 210 and conductors 216. Finally, solder balls 214 are dropped into recesses 214 and reflowed as shown in FIG. 4F. Substrate 204 may then be diced from its panel or wafer (not illustrated) at this time to complete the manufacturing process. The manufacturing process will now be summarized in the following flowchart.

### Example Manufacturing Process Flowchart

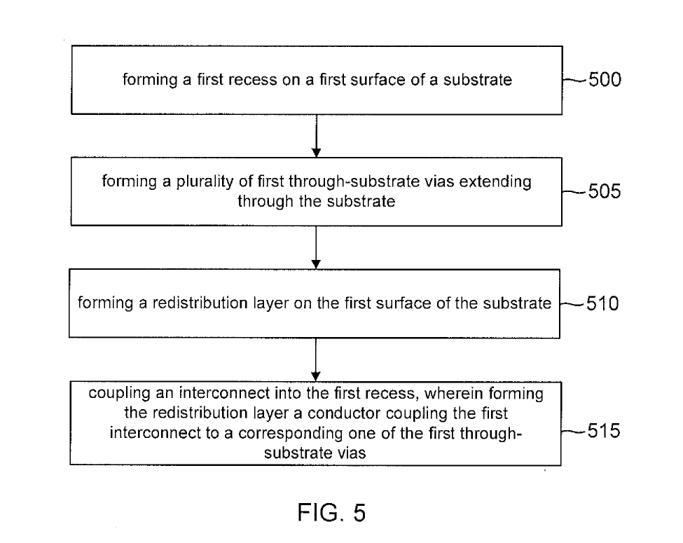

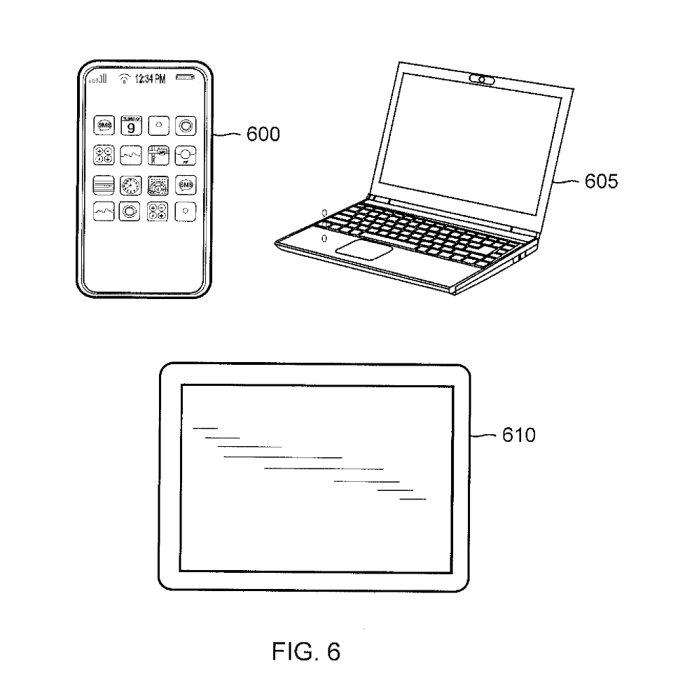

A flowchart for an example method of manufacture is shown in FIG. 5. The method includes a step 500 of forming a first recess on a first surface of a substrate. A step 505 comprises forming a plurality of first through-substrate vias extending through the substrate. Vias 202a through 202d of FIG. 2 are examples of such first through-substrate vias. A step 510 comprises forming a redistribution layer on the first surface. Finally, a step 515 comprises coupling an interconnect into the first recess, wherein forming the redistribution layer forms a conductor coupling the first interconnect to a corresponding one of the first through-substrate vias. For example, forming redistribution layer 220 of FIG. 2 couples conductor 216a between solder ball 212 in recess 214a to first through-substrate via 202b. In that regard, note that some recesses such as recess 214d of FIG. 3A receive a solder ball 212 that does not couple to any through-substrate vias through any redistribution layer conductors. Some example electronic systems that may advantageously incorporate a low-profile passive-on-package will now be discussed.

### Example Electronic Systems

The passive-on-packages disclosed herein may be incorporated into a wide variety of electronic systems. For example, as shown in FIG. 6, a cell phone 600, a laptop 605, and a tablet PC 610 may all include a low-profile passive-on-package constructed in accordance with the disclosure. Other exemplary electronic systems such as a music player, a video player, a communication device, and a personal computer may also be configured with passive-on-packages constructed in accordance with the disclosure.

As those of some skill in this art will by now appreciate and depending on the particular application at hand, many modifications, substitutions and variations can be made in and to the materials, apparatus, configurations and methods of use of the devices of the present disclosure without departing from the spirit and scope thereof. In light of this, the scope of the present disclosure should not be limited to that of the particular embodiments illustrated and described herein, as they are merely by way of some examples thereof, but rather, should be fully commensurate with that of the claims appended hereafter and their functional equivalents.

We claim:

1. A device, comprising:
a substrate;
a first recess on a first surface of the substrate;
a plurality of first through-substrate vias extending through the substrate;
a first interconnect, wherein the first interconnect is received by the first recess; and
a redistribution layer on the first surface of the substrate, wherein the redistribution layer is configured to electrically couple the first interconnect to a corresponding one of the first through-substrate vias.

2. The device of claim 1, further comprising:
a second recess on the first surface of the substrate; and
a second through-substrate via extending through the substrate from the second recess.

3. The device of claim 1, further comprising a capacitor adjacent an opposing second surface of the substrate, wherein the second through-substrate via electrically couples to the capacitor.

4. The device of claim 1, further comprising an embedded inductor, wherein the embedded inductor comprises at least two of the first through-substrate vias.

5. The device of claim 4, wherein the embedded inductor comprises a plurality of embedded inductors.

6. The device of claim 5, wherein each embedded inductor comprises two first through-substrate vias electrically coupled together through a conductor adjacent an opposing second surface of the substrate.

7. The device of claim 1, wherein the substrate comprises a glass substrate, and wherein the first interconnect comprises a solder ball.

8. The device of claim 1, wherein the substrate comprises a semiconductor substrate, and wherein the first interconnect comprises a metal pillar.

9. The device of claim 1, wherein the substrate comprises an organic substrate, and wherein the first interconnect comprises a solder ball.

10. The device of claim 1, further comprising:
a second recess on the first surface of the substrate; and
a second interconnect received by the second recess, wherein the first and second interconnects comprise solder balls, and wherein the second solder ball has only a mechanical function with respect to securing the device to a circuit board.

11. A method, comprising:
forming a first recess on a first surface of a substrate;
forming a plurality of first through-substrate vias extending through the substrate;
forming a redistribution layer adjacent the first surface of the substrate; and
coupling a first interconnect into the first recess, wherein forming the redistribution layer forms a conductor coupling the first interconnect to a corresponding one of the first through-substrate vias.

12. The method of claim 11, wherein forming the redistribution layer comprises patterning a metal layer on the first surface.

13. The method of claim 12, wherein patterning the metal layer further comprises patterning a pad in the first recess.

14. The method of claim 13, wherein patterning the metal layer comprises patterning a copper metal layer.

15. The method of claim 11, wherein forming a first recess further comprises forming a second recess on the first surface of the substrate, the method further comprising:
forming a second through-substrate via extending through the substrate from the second recess.

16. The method of claim 15, wherein forming the second recess comprises forming a plurality of second recesses, and wherein forming the second through-substrate via comprises forming a plurality of second through-substrate vias corresponding to the plurality of second recesses, each second through-substrate via extending through the substrate from the corresponding second recess.

17. The method of claim 15, further comprising forming a capacitor on an opposing second surface of the substrate that is coupled to at least one of the second through-substrate vias.

18. The method of claim 14, further comprising depositing a passivation layer on the first surface of the substrate and on an opposing second surface of the substrate.

19. The method of claim 14, wherein forming the recesses comprising etching the first side of a glass substrate.

20. The method of claim 14, wherein attaching an interconnect in each recess comprises dropping a solder ball into each recess.

21. A device, comprising:
a substrate;
an embedded inductor extending through the substrate;
a first recess on a first surface of the substrate;
a second recess on the first surface of the substrate;
a first interconnect received by the first recess;
a second interconnect received by the second recess; and
means for electrically coupling the first interconnect to the embedded inductor and for electrically coupling the second interconnect to the embedded inductor.

22. The device of claim 1, wherein the first interconnect and the second comprise solder balls.

23. The device of claim 21, wherein the substrate comprises a glass substrate having a thickness of at least 100 microns.

24. The device of claim 23, wherein the glass substrate has a thickness of at least 150 microns.

25. The device of claim 21, wherein the means comprises at least one patterned metal layer.

26. A package, comprising:
a substrate having a first side separated by a substrate thickness from an opposing second side;
a plurality of recesses on the first side of the substrate;
a plurality of solder balls corresponding to the plurality of recesses, each solder ball having a solder ball diameter and each recess receiving the corresponding solder ball such that a package height for the package is less than a sum of the substrate thickness and the solder ball diameter;
a plurality of through-substrate vias extending from the first side and each having a length substantially equal to the substrate thickness; and
a redistribution layer configured to electrically couple certain ones of the solder balls to corresponding ones of the through-substrate vias.

27. The package of claim 26, wherein the package is incorporated into at least one of a cellphone, a laptop, a tablet, a music player, a communication device, a computer, and a video player.

28. The package of claim 26, wherein the substrate is a glass substrate.

29. The package of claim 26, further comprising an embedded inductor, wherein the embedded inductor includes a pair of the through-substrate vias.

30. The package of claim 26, wherein the substrate is a semiconductor substrate.
